(19) United States
(12) Patent Application Publication
(10) Pub. No.: US 2025/0226297 A1
(43) Pub. Date: Jul. 10, 2025

(54) PACKAGE WITH CARRIER HAVING PLATED BOTTOM SURFACE AND SIDEWALL

(71) Applicant: Infineon Technologies AG, Neubiberg (DE)

(72) Inventors: Kok Yau CHUA, Melaka (MY); Soon Lock GOH, Melaka (MY); Chee Hong LEE, Melaka (MY); Swee Kah LEE, Melaka (MY); Luay Kuan ONG, Melaka (MY); Norbert PIELMEIER, Regensburg (DE)

(73) Assignee: Infineon Technologies AG, Neubiberg (DE)

(21) Appl. No.: 19/001,983

(22) Filed: Dec. 26, 2024

(30) Foreign Application Priority Data
Jan. 4, 2024 (DE) 10 2024 100 197.6

(51) Int. Cl. H01L 23/495; H01L 23/31

(52) U.S. Cl. CPC H01L 23/49582; H01L 23/3157

(57) ABSTRACT

A package and method is disclosed. In one example, the package comprises a carrier, an electronic component mounted on the carrier, and an encapsulant at least partially encapsulating the electronic component and partially encapsulating the carrier. At least a portion of a bottom surface and at least a portion of a sidewall of the carrier are exposed beyond the encapsulant. Said at least portion of the bottom surface and said at least portion of the sidewall are covered at least partially by a plating structure.

### CROSS-REFERENCE TO RELATED APPLICATION

This Utility Patent Application claims priority to German Patent Application No. 10 2024 100 197.6 filed Jan. 4, 2024, which is incorporated herein by reference. Background

### TECHNICAL FIELD

Various embodiments relate generally to a package, and a method of manufacturing a package.

### DESCRIPTION OF THE RELATED ART

A conventional package may comprise an electronic component mounted on a carrier, may be electrically connected from the electronic component to the carrier or to a lead, and may be molded using a mold compound as an encapsulant.

Electric reliability and the manufacturing effort of a conventional package may be an issue.

### SUMMARY

There may be a need for a package with high electric reliability and reasonable or low manufacturing effort.

According to an exemplary embodiment, a package is provided which comprises a carrier, an electronic component mounted on the carrier, and an encapsulant at least partially encapsulating the electronic component and partially encapsulating the carrier, wherein at least a portion of a bottom surface and at least a portion of a sidewall of the carrier are exposed beyond the encapsulant, wherein said at least portion of the bottom surface and said at least portion of the sidewall are covered at least partially by a plating structure having one of the following: A) said at least portion of the bottom surface is directly covered by a tin plating layer, which is further covered by at least one other plating layer, and said at least portion of the sidewall is directly covered by the at least one other plating layer; or B) said at least portion of the bottom surface and said at least portion of the sidewall are directly covered by a common tin plating layer, and at least part of at least one other plating layer is deposited on the tin plating layer; or C) said at least portion of the bottom surface and said at least portion of the sidewall are directly covered by at least one plating layer made of an electrically conductive material different from tin.

According to another exemplary embodiment, a method of manufacturing packages is provided, the method comprising mounting electronic components, at least one for each package being manufactured, on a carrier structure provided for the plurality of packages in common, at least partially encapsulating the electronic components and partially encapsulating the carrier structure by an encapsulant structure provided for the plurality of packages in common, after the encapsulating, selectively removing exposed material of the carrier structure at least between adjacent packages being manufactured, and by a separate subsequent process, fully separating the packages by removing material, which has been exposed by said selectively removing, of the encapsulant structure between adjacent packages, wherein said selectively removing exposed material comprises applying a tin layer covering part of the carrier structure which will be used as electrical terminals of the packages, and removing selectively an exposed part of the carrier structure being not covered by the tin layer by an alkaline etching process so as to disconnect adjacent sections of the carrier structure covered by the tin layer.

According to an exemplary embodiment related to the above described manufacturing method, electronic components may be mounted on a carrier structure and may be at least partially encapsulated by an encapsulant, while the carrier structure may be only partially encapsulated. Advantageously, exposed material of the carrier structure between adjacent packages being manufactured may be removed in a process to be executed before fully separating the packages from each other for obtaining individual and separated packages. Advantageously, said selective removal of material of the carrier structure between adjacent packages may make use of an applied tin layer (i.e. a layer comprising or consisting of tin) covering part of the carrier structure for protecting said part against material removal. By removing selectively an exposed part of the carrier structure being not covered by the tin layer using an alkaline etching process, adjacent sections of the carrier structure covered by the tin layer may be separated from each other. To put it shortly, the tin layer—for instance in addition to its function as solderable plating layer—synergistically acts as etching mask for defining portions of the carrier structure to be removed by the alkaline etching process and for defining portions of the carrier structure which shall not be removed by the alkaline etching process. This may render the manufacturing process simple and accurate. Further advantageously, by separating the carrier structure into separated carriers for individual packages prior to the actual separation of the individual packages from a common integral structure during a batch manufacturing process may make it possible that the subsequent separate package separation process can be carried out without the need of removing metallic carrier material. In contrast to this, said package separation process may only have to cut through encapsulant material, which may be done significantly easier and faster.

For instance as a result of the described manufacturing process, packages according to exemplary embodiments may be obtained having at least one electronic component mounted on a carrier and being encapsulated by an encapsulant. As a fingerprint of the described manufacturing process, A) a portion of the bottom surface of the carrier may be directly covered by a tin plating layer, which may be further covered by another plating layer, wherein also a sidewall of the carrier may be directly covered by said other plating layer (see for example the embodiments of FIG. 3 or FIG. 4 with the option indicated by reference signs 150). In another embodiment B), the bottom surface and the sidewall of the carrier may be directly covered by a common tin plating layer, whereas another plating layer may be deposited on the tin plating layer (see for example the embodiment of FIG. 2A). In still another embodiment C), the bottom surface and the sidewall of the carrier may be directly covered by a non-tin plating layer (see for example the embodiments of FIG. 3 or FIG. 4 with the option indicated by reference signs 152). All of these packages may be manufactured with high electric reliability and reasonable or low manufacturing effort.

### BRIEF DESCRIPTION OF THE DRAWINGS

The accompanying drawings, which are included to provide a further understanding of exemplary embodiments and constitute a part of the specification, illustrate exemplary embodiments.

In the drawings:

FIG. 1 illustrates a cross-sectional view of a package according to an exemplary embodiment.

FIG. 2A illustrates a cross-sectional view of a structure obtained during manufacturing a package according to an exemplary embodiment.

FIG. 2B illustrates a cross-sectional view of a package according to another exemplary embodiment.

FIG. 3 illustrates cross-sectional views of structures obtained during manufacturing a package according to an exemplary embodiment.

FIG. 4 illustrates cross-sectional views of structures obtained during manufacturing a package according to another exemplary embodiment.

FIG. 5 illustrates cross-sectional views of structures obtained during manufacturing a package according to still another exemplary embodiment.

FIG. 6 illustrates plan views of structures obtained during manufacturing a package according to an exemplary embodiment.

FIG. 7 illustrates plan views of structures obtained during manufacturing a package according to another exemplary embodiment.

FIG. 8 illustrates images obtained during manufacturing a package according to an exemplary embodiment.

FIG. 9 illustrates a flowchart of a method of manufacturing a package according to an exemplary embodiment.

FIG. 10 illustrates images obtained during manufacturing a package according to an exemplary embodiment.

### DETAILED DESCRIPTION

There may be a need for a package with high electric reliability and reasonable or low manufacturing effort.

According to an exemplary embodiment, a package is provided which comprises a carrier, an electronic component mounted on the carrier, and an encapsulant at least partially encapsulating the electronic component and partially encapsulating the carrier, wherein at least a portion of a bottom surface and at least a portion of a sidewall of the carrier are exposed beyond the encapsulant, wherein said at least portion of the bottom surface and said at least portion of the sidewall are covered at least partially by a plating structure having one of the following: A) said at least portion of the bottom surface is directly covered by a tin plating layer, which is further covered by at least one other plating layer, and said at least portion of the sidewall is directly covered by the at least one other plating layer; or B) said at least portion of the bottom surface and said at least portion of the sidewall are directly covered by a common tin plating layer, and at least part of at least one other plating layer is deposited on the tin plating layer; or C) said at least portion of the bottom surface and said at least portion of the sidewall are directly covered by at least one plating layer made of an electrically conductive material different from tin.

According to another exemplary embodiment, a method of manufacturing packages is provided, the method comprising mounting electronic components, at least one for each package being manufactured, on a carrier structure provided for the plurality of packages in common, at least partially encapsulating the electronic components and partially encapsulating the carrier structure by an encapsulant structure provided for the plurality of packages in common, after the encapsulating, selectively removing exposed material of the carrier structure at least between adjacent packages being manufactured, and by a separate subsequent process, fully separating the packages by removing material, which has been exposed by said selectively removing, of the encapsulant structure between adjacent packages, wherein said selectively removing exposed material comprises applying a tin layer covering part of the carrier structure which will be used as electrical terminals of the packages, and removing selectively an exposed part of the carrier structure being not covered by the tin layer by an alkaline etching process so as to disconnect adjacent sections of the carrier structure covered by the tin layer.

According to an exemplary embodiment related to the above described manufacturing method, electronic components may be mounted on a carrier structure and may be at least partially encapsulated by an encapsulant, while the carrier structure may be only partially encapsulated. Advantageously, exposed material of the carrier structure between adjacent packages being manufactured may be removed in a process to be executed before fully separating the packages from each other for obtaining individual and separated packages. Advantageously, said selective removal of material of the carrier structure between adjacent packages may make use of an applied tin layer (i.e. a layer comprising or consisting of tin) covering part of the carrier structure for protecting said part against material removal. By removing selectively an exposed part of the carrier structure being not covered by the tin layer using an alkaline etching process, adjacent sections of the carrier structure covered by the tin layer may be separated from each other. To put it shortly, the tin layer—for instance in addition to its function as solderable plating layer—synergistically acts as etching mask for defining portions of the carrier structure to be removed by the alkaline etching process and for defining portions of the carrier structure which shall not be removed by the alkaline etching process. This may render the manufacturing process simple and accurate. Further advantageously, by separating the carrier structure into separated carriers for individual packages prior to the actual separation of the individual packages from a common integral structure during a batch manufacturing process may make it possible that the subsequent separate package separation process can be carried out without the need of removing metallic carrier material. In contrast to this, said package separation process may only have to cut through encapsulant material, which may be done significantly easier and faster.

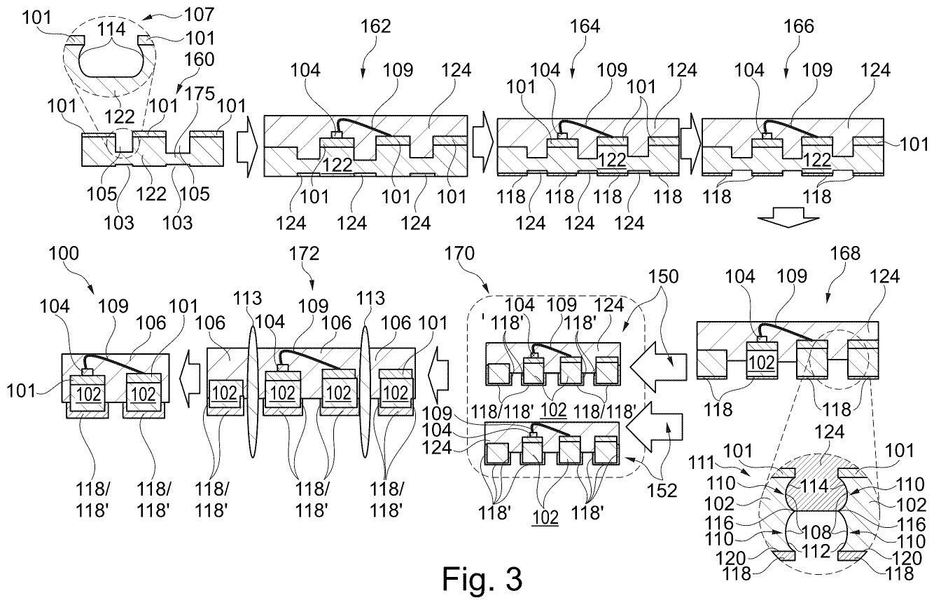

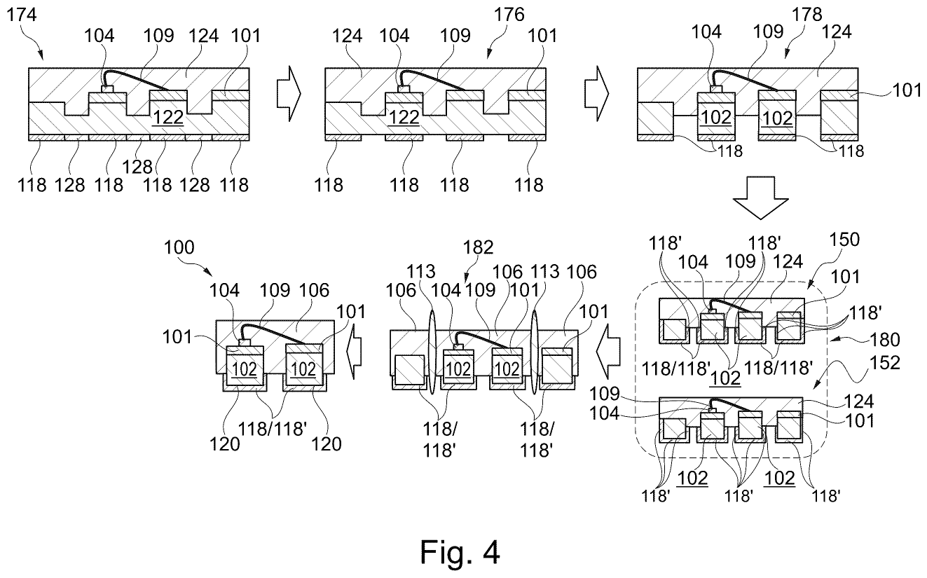

For instance as a result of the described manufacturing process, packages according to exemplary embodiments may be obtained having at least one electronic component mounted on a carrier and being encapsulated by an encapsulant. As a fingerprint of the described manufacturing process, A) a portion of the bottom surface of the carrier may be directly covered by a tin plating layer, which may be further covered by another plating layer, wherein also a sidewall of the carrier may be directly covered by said other plating layer (see for example the embodiments of FIG. 3 or FIG. 4 with the option indicated by reference signs 150). In another embodiment B), the bottom surface and the sidewall of the carrier may be directly covered by a common tin plating layer, whereas another plating layer may be deposited on the tin plating layer (see for example the embodiment of FIG. 2A). In still another embodiment C), the bottom surface and the sidewall of the carrier may be directly covered by a non-tin plating layer (see for example the embodiments of FIG. 3 or FIG. 4 with the option indicated by reference signs 152). All of these packages may be manufactured with high electric reliability and reasonable or low manufacturing effort.

### Description of Further Exemplary Embodiments

In the following, further exemplary embodiments of the package and the method will be explained.

In the context of the present application, the term “package” may particularly denote an electronic device which may comprise one or more electronic components mounted on a (in particular electrically conductive) carrier. Said constituents of the package may be encapsulated by an encapsulant. Optionally, one or more electrically conductive interconnect bodies (such as metallic pillars, pumps, bond wires and/or clips) may be implemented in a package, for instance for electrically coupling and/or mechanically supporting the electronic component.

In the context of the present application, the term “carrier” may particularly denote a support structure (which may be at least partially electrically conductive) which serves as a mechanical support for the electronic component(s) to be mounted thereon, and which may also contribute to the electric interconnection between the electronic component(s) and the periphery of the package. In other words, the carrier may fulfil a mechanical support function and an electric connection function. A carrier may comprise or consist of a single part, multiple parts joined via encapsulation or other package components, or a subassembly of carriers. When the carrier forms part of a leadframe, it may be or may comprise a die pad. For instance, such a carrier may be a leadframe structure (for instance made of copper), a DAB (Direct Aluminum Bonding) substrate, a DCB (Direct Copper Bonding) substrate, etc. Moreover, the carrier may also be configured as Active Metal Brazing (AMB) substrate.

In the context of the present application, the term “carrier structure” may particularly denote an electrically conductive structure composed of a plurality of (for instance integrally connected) carriers, each for a respective package. During a batch manufacturing process, the carrier structure may be processed in common for the plurality of packages to be manufactured, before being separated into individual carriers for obtaining individual packages. For instance, the carrier structure may be a leadframe or a substrate in panel form.

In the context of the present application, the term “electronic component” may in particular encompass a semiconductor chip (in particular a power semiconductor chip), an active electronic device (such as a transistor), a passive electronic device (such as a capacitance or an inductance or an ohmic resistance), a sensor (such as a microphone, a light sensor or a gas sensor), an actuator (for instance a loudspeaker), and a microelectromechanical system (MEMS). However, in other embodiments, the electronic component may also be of different type, such as a mechatronic member, in particular a mechanical switch, etc. In particular, the electronic component may be a semiconductor chip having at least one integrated circuit element (such as a diode or a transistor in a surface portion thereof. The electronic component may be a bare die or may be already packaged or encapsulated. Semiconductor chips implemented according to exemplary embodiments may be formed in silicon technology, gallium nitride technology, silicon carbide technology, etc.

In the context of the present application, the term “encapsulant” may particularly denote a substantially electrically insulating material surrounding an electronic component and a carrier to provide mechanical protection, electrical insulation, and optionally a contribution to heat removal during operation. In particular, said encapsulant may be a mold compound. A mold compound may comprise a matrix of flowable and hardenable material and filler particles embedded therein. For instance, filler particles may be used to adjust the properties of the mold component, in particular to enhance thermal conductivity. As an alternative to a mold compound (for example on the basis of epoxy resin), the encapsulant may also be a potting compound (for instance on the basis of a silicone gel).

In the context of the present application, the term “encapsulant structure” may particularly denote an electrically insulating structure composed of a plurality of (in particular integrally connected) encapsulants, each for a respective package. During a batch manufacturing process, the encapsulant structure may be processed in common for the plurality of packages to be manufactured, before being separated into individual encapsulants for obtaining individual packages. For instance, the encapsulant structure may be a common mold body.

In the context of the present application, the term “plating structure” may particularly denote an electrically conductive structure formed by plating (for instance electroless plating and/or electroplating). Said plating structure may be made of a solderable material. For instance, the material of the plating structure may be solderable by itself and/or may have appropriate wetting properties in terms of soldering.

In the context of the present application, the term “electrical terminal” may particularly denote an electrically conductive interface of the package, for example a pad or lead. By such an electrical terminal, electric signals and/or electric energy can be transmitted between the package and an electronic periphery.

In the context of the present application, the term “selectively removing exposed carrier material” may particularly denote a process during which only or predominantly carrier material being exposed beyond a tin layer may be removed, whereas carrier material being covered by the tin layer may be predominantly or entirely prevented from being removed by the selective removal process. As a result, the tin layer may act as a protection against material removal below, for instance may act as an etching mask.

In the context of the present application, the term “alkaline etching process” may particularly denote a process of selectively removing (in particular metallic) carrier material (in particular copper) while being incapable of efficiently removing tin material. Such an alkaline etching process may use an alkaline etchant which may comprise for example ammonium chloride. For instance, an ammoniacal etching solution, cupric chloride, copper chloride, etc. may be used for an alkaline etchant.

In the context of the present application, the term “main surface” of a body may particularly denote a body surface of one of the largest body surfaces, more particularly a body surface of one of the two largest body surfaces. For instance, the body may have two opposing main surfaces separated by body material and connected with each other by a circumferential edge defined by a plurality of sides.

In an embodiment, at least part of the sidewall of the carrier is curved, for example concavely curved, and has an undercut. By providing a curvature to at least part of the sidewall, the sidewall area may be increased. When a plating layer is formed thereon, said increased surface area may have a positive impact on adhesion. This may be particularly advantageous when an undercut is formed at the curved sidewall surface, since this may provide an anchoring effect promoting integral connection of the constituents of the package. Such a curved sidewall surface may be a fingerprint of an alkaline etching process.

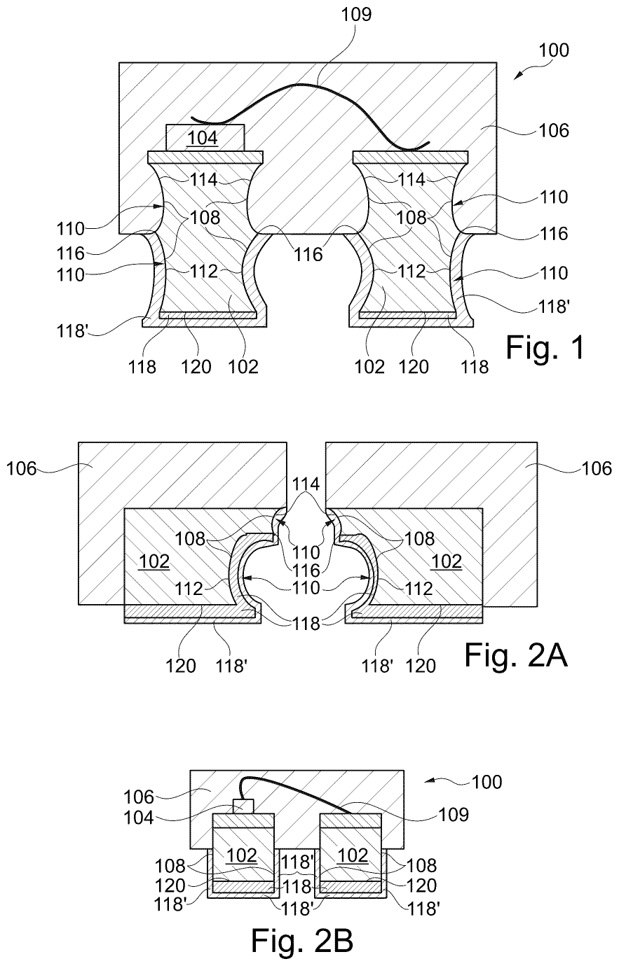

In an embodiment, the sidewall comprises a lower curved part and an upper curved part connected at an edge (see for example FIG. 1 to FIG. 3). For example, at least one of said curved parts may be formed by an alkaline etching process. More precisely, one curved part may be formed by an alkaline etching process carried out when separating different carriers from a common carrier structure during a batch manufacturing process. Another curved part may be formed by an etching process during a leadframe manufacturing process. A curved part formed by an etching process during a leadframe manufacturing process may be an upper curved part and/or a lower curved part. Referring for example to the leadframe design of the first image of FIG. 3, the illustrated leadframe design has bottom recesses and top recesses (at least one of which may be optional) which may be formed by etching during leadframe manufacture and which may each lead to a curved sidewall part. Another curved part of a carrier sidewall may be formed by an alkaline etching process using a tin plating layer as etching mask, and may lead to an upper or a lower curved sidewall part. For example, when a leadframe design with top recesses only and without bottom recesses is used, a lower curved part may be due to an alkaline etching process using a tin plating layer as etching mask, and an upper curved part may be due to the top recesses in the leadframe. When however a leadframe design with bottom recesses is used, an upper curved part due to an alkaline etching process using a tin plating layer as etching mask may be above a lower curved part due to the bottom recesses in the leadframe. By an edge between the mentioned two concave parts, an undercut may be formed which may create an anchoring structure improving the mechanical integrity of the package. For example, the edge can be characterized by a plated curve intersecting a non-plated curve.

In an embodiment, the bottom surface and the lower curved part are covered by the same plating structure. Such a configuration, which is shown for instance in FIG. 2A, may simplify the manufacturing process, since only a single plating structure may be formed (for instance made of tin) both for the bottom surface and a lower part of the sidewall.

In an embodiment, the electrically conductive material different from tin is electroless nickel immersion gold (ENIG), NiPdAu and/or NiPAu. Other non-tin surface finish alloys or metals may be possible as well. However, ENIG, NiPdAu and/or NiPAu show excellent properties in terms of soldering and wetting properties.

In an embodiment, said at least one other plating layer is made of a different material, preferably ENIG, NiPdAu and/or NiPAu, than the tin plating layer, and said at least portion of the sidewall is directly covered by the at least one other plating layer without the tin plating layer in between. Thus, tin can be combined in a plating structure with a non-tin material for further improving solderability. However, it is also possible to apply a further tin plating layer on an already existing tin plating layer, i.e. tin on tin.

In an embodiment, the electronic component is configured as a power die. Hence, the electronic component may be configured as a power semiconductor chip. Thus, the electronic component (such as a semiconductor chip) may be used for power applications for instance in the automotive field and may for example have at least one integrated insulated-gate bipolar transistor (IGBT) and/or at least one transistor of another type (such as a MOSFET, a JFET, a HEMT, etc.) and/or at least one integrated diode. Such integrated circuit elements may be manufactured for instance in silicon technology or based on wide-bandgap semiconductors (such as silicon carbide, gallium nitride). A semiconductor power chip may comprise one or more field effect transistors, diodes, inverter circuits, half-bridges, full-bridges, drivers, logic circuits, further devices, etc.

In an embodiment, the package is configured as power package. A power package may be a package comprising at least one power chip as encapsulated electronic component. Thus, the package may be configured as power module, for instance molded power module such as a semiconductor power package. For instance, an exemplary embodiment of the package may be an intelligent power module (IPM). Another exemplary embodiment of the package is a dual inline package (DIP).

In an embodiment, the carrier comprises copper at least at its bottom surface or consists of copper. It has been found that copper can be efficiently etched by an alkaline etching solution and is therefore a highly appropriate material for the carrier. Furthermore, copper has a very high electric and thermal conductivity, which is advantageous during operation of the package in terms of low loss electric signal transmission and excellent heat removal.

In an embodiment, the carrier is a leadframe structure. Correspondingly, the method may comprise using a leadframe as the carrier structure. Said leadframe may be in particular an integral body comprising a plurality of leadframe structures Thus, the carrier may comprise a leadframe-type structure. A leadframe may be a metal structure that carries signals from the electronic component to the outside, and/or in opposite direction. The leadframe may comprise a central die pad, on which the electronic component is placed, surrounded by one or more leads, i.e. metal conductors leading away from the electronic component to the electronic periphery of the package, and/or in opposite direction.

In an embodiment, the method comprises, before the applying of the tin layer, applying a mask covering part of a bottom surface of the carrier structure, so as to expose another part of the bottom surface of the carrier structure for the subsequent applying of the tin layer. By providing a patterned layer forming a mask on defined surface portions of a bottom of the carrier structure, other exposed surface portions of the bottom of the carrier structure may be defined on which a subsequent deposition process (in particular a plating process) will lead to the formation of a tin layer in a selective way. The mask may be made of material on which tin deposition does not occur or on which tin does not adhere. After formation of the tin pattern, the mask can be removed (for instance by selective etching).

In an embodiment, before said selectively removing the exposed part of the carrier structure, the method comprises at least partially removing at least one of:
a) material of the encapsulant structure between adjacent parts of the carrier structure covered by the tin layer. During encapsulation, for instance during molding, encapsulant sections may fill recesses on a bottom side of the carrier structure to thereby form a mask-like pattern which may be used for defining exposed surface portions of the bottom of the carrier structure for subsequent tin deposition. Before etching away defined sections of the carrier structure by an alkaline etching process, such encapsulant sections may be removed.
b) a resist mask between adjacent parts of the carrier structure covered by the tin layer, the resist mask being applied before the encapsulating. Before encapsulation, a mask pattern may be formed for defining regions of the bottom of the carrier structure which shall not be covered by tin in a subsequent tin deposition process. Before etching away defined sections of the carrier structure by an alkaline etching process, such a resist mask applied before encapsulating may be removed.
c) a resist mask between adjacent parts of the carrier structure covered by the tin layer, the resist mask being applied after the encapsulating and before the applying of the tin layer. After encapsulation, a mask pattern may be applied for defining regions of the bottom of the carrier structure which shall not be covered by tin in a subsequent tin deposition process. Before etching away defined sections of the carrier structure by an alkaline etching process, such a resist mask applied after encapsulating may be removed.

In an embodiment, after said removing by the alkaline etching process, the method further comprises removing the tin layer from a bottom surface of the carrier structure, and depositing at least one additional electrically conductive layer on the bottom surface of the carrier structure and a sidewall of the carrier structure exposed by the alkaline etching process. For example, corresponding embodiments are indicated by reference sign 152 in FIG. 3 and FIG. 4. The tin mask used for selectively removing carrier material during alkaline etching may then be removed, and a freely definable electrically conductive layer (for instance a plating layer) may be formed on bottom and sidewall of the carrier. Preferably, the outermost surface of the at least one additional electrically conductive layer comprises a material different from tin. For instance, the at least one additional electrically conductive layer can be made of NiPdAu, which may be formed for example by plating.

In an embodiment, after said removing by the alkaline etching process, the method further comprises depositing at least one additional conductive layer (for example a further tin layer) on a bottom surface of the carrier structure and on a sidewall of the carrier structure exposed by the alkaline etching process. For example, such embodiments are indicated by reference sign 150 in FIG. 3 and FIG. 4. The tin mask used for selectively removing carrier material during alkaline etching may remain as a solderable plating layer which may have appropriate properties in terms of solderability. Said tin may be subsequently thickened and extended also to a sidewall of the carrier by the formation of the additional electrically conductive layer. Preferably, the outermost surface of the at least one additional electrically conductive layer comprises a material different from tin. For instance, the at least one additional electrically conductive layer can be made of NiPdAu, which may be formed for example by plating. Alternatively, a second tin layer may be applied on the first tin layer and may extend not only along the bottom of the carrier but also along a sidewall of the carrier. Such embodiments have the advantage that the tin mask does not have to be removed after selective etching, but may be used as part of a surface finish or plating on the remaining carrier. This may simplify the manufacturing process.

In an embodiment, the separate subsequent process is a mechanical dicing process, wherein this dicing process is executed without cutting metal of the carrier structure. Alternatively, a laser dicing process may be used. During dicing, cutting through metallic material may significantly reduce the speed of the separation process. By removing the metallic material of the carrier in a dicing street by the alkaline etching process prior to dicing, it may be possible to dice only through encapsulant material. This may significantly accelerate the package separation process.

In an embodiment, the method comprises forming the tin layer and/or the at least one additional conductive layer by a plating process. Such a plating process may denote the formation of a metallic material, for instance by electroless plating (for instance chemically or by physical vapor deposition) or by electroplating (in particular galvanic plating).

In an embodiment, the method comprises concavely curving at least part of a sidewall of the carrier structure by the alkaline etching process, while a bottom surface of the carrier structure is formed planar without being etched. When executing an alkaline etching process, the etching process and the etchant may be adjusted so that an etching anisotropy is achieved which leads to a concave curvature of at least part of the carrier structure's sidewall. Such a concave curvature may increase a surface area to be plated and may thus have a positive impact on adhesion and/or may provide a mechanical anchoring effect.

In an embodiment, the selectively removing and the separate subsequent process remove material along the same direction. To put it shortly, the selective removal process may remove carrier material along a thickness direction of the packages to be formed for thinning without fully separating the packages. The subsequent material removal process may then remove encapsulant material also along the thickness direction of the packages to be formed until the individual packages are separated from each other.

In an embodiment, the selectively removing locally thins an arrangement composed of the carrier structure and the encapsulant structure, and the separate subsequent process forms a through hole extending through said arrangement. While the selective removal process removes exposed carrier material for vertical thinning, the subsequent separation process removes encapsulant material for separating a common structure into individual packages.

In an embodiment, selectively removing material of the carrier structure comprises selectively removing metallic material, for example selectively removing copper material. By such a selective etching process, substantially no encapsulant material and substantially no mask material may be removed, or the etch rate of such material may be at least significantly lower than the etch rate of copper material of the carrier structure.

In an embodiment, the separate subsequent process does not remove metallic material. This leads to a very fast separation process.

In an embodiment, the package comprises an electrically conductive coupling element electrically coupling the electronic component with the carrier. Such an electrically conductive coupling element may be a clip, a bond wire or a bond ribbon. A clip may be a curved electrically conductive plate body accomplishing an electric connection with a high connection area to a main surface of a respective electronic component. Additionally or alternatively to such a clip, it is also possible to implement one or more other electrically conductive interconnect bodies in the package, for instance a bond wire and/or a bond ribbon connecting the electronic component with the carrier and/or a lead or connecting different pads of an electronic component.

As substrate or wafer forming the basis of the electronic component(s), a semiconductor substrate, in particular a silicon substrate, may be used. Alternatively, a silicon oxide or another insulator substrate may be provided. It is also possible to implement a germanium substrate or a III-V-semiconductor material. For instance, exemplary embodiments may be implemented in GaN or SiC technology.

The above and other objects, features and advantages will become apparent from the following description and the appended claims, taken in conjunction with the accompanying drawings, in which like parts or elements are denoted by like reference numbers.

The illustration in the drawing is schematically and not to scale.

Before exemplary embodiments will be described in more detail referring to the figures, some general considerations will be summarized based on which exemplary embodiments have been developed.

Conventionally, a copper leadframe in strip or panel form or a copper sheet (chip embedding) may be used as a common carrier for power devices, due to its good electrical and thermal conductivity and its simple construction. Power packages may have thick copper structures along their saw street. This results in complications in a package singulation process for removing mold compound and copper leadframe material. This may slow down the sawing process speed. During a conventional package singulation process, a compromise may be made between process speed (and therefore process throughput) and singulation quality (in particular which concerns the formation of artifacts such as burr and particles).

In another conventional approach, a tie-bar less carrier (for example laminate substrate, routable pre-mold frame, etc.) may be implemented which may allow a faster singulation. However, limitations of such an approach are higher material cost, and the fact that a tie-bar less carrier is an uncommon carrier option for power application.

Also a partial etch leadframe technology has been considered in conventional approaches. However, limitations of said approach are higher process costs due to precision masking (in particular using a photo-resist) and etching.

According to an exemplary embodiment, electronic components mounted on a carrier structure are encapsulated by an encapsulant, while part of the carrier structure may remain exposed. An exposed carrier structure portion may be removed prior to singulating packages from a previous integral multi-package structure. Advantageously, the described selective carrier material removal between adjacent packages may be spatially defined by a patterned tin layer applied only on part of the carrier structure. During an alkaline etching process for selectively removing carrier material (preferably copper), the patterned tin layer may function as an etch mask and may lead to a simple and well-defined manufacture. Due to the separation of defined portions of the carrier structure into individual carriers before singulation of the individual packages by dicing or the like, it may be advantageously dispensable that the dicing process removes metallic carrier material. In contrast to this, that package separation process may only have to cut through the encapsulant, which allows to speed-up singulation.

With the mentioned manufacturing architecture, packages of exemplary embodiments may be created having one or more encapsulated electronic components assembled on a carrier. As a result of the above described manufacture, at least one of the following may be obtained:
A) A bottom surface of the carrier may be directly covered by tin, which may be covered, in turn, by a further plating layer. A sidewall of the carrier may also be directly covered by said further plating layer (see for example the embodiments of FIG. 3 or FIG. 4 denoted with reference signs 150).
B) The bottom surface and the sidewall of the carrier may be directly covered by tin, and a further plating layer may be formed on the tin (see for example the embodiment of FIG. 2A).
C) The bottom surface and the sidewall of the carrier may be directly covered by a plating layer which does not comprise tin (see for example the embodiments of FIG. 3 or FIG. 4 denoted with reference signs 152).

The packages obtained from the above-described manufacturing process may be produced in a simple way and with high reliability and performance.

A gist of an exemplary embodiment may be to selectively remove a carrier portion (in particular copper structures) along a dicing line (for instance along a saw street) prior to package singulation. A selectivity of a corresponding etching process can be achieved by applying a tin material, which is inert to the etching chemicals, all-over the leadframe surfaces as protections, except the dicing line (for instance saw street) locations. Depending on the type of material applied, a cleaning and/or a removal process of the applied material may be advantageous before the etching process.

Exemplary embodiments may have advantages: For instance, they may prevent copper burr, lead delamination, solderability fails, and particles issues. A further advantage may be that it may be possible to use existing leadframe material, preferably of copper. A singulation process may become free of mechanical stress. Furthermore, it may be possible to speed up a subsequent package singulation process. This may simplify and accelerate the singulation process. Moreover, it may be possible to reduce or even eliminate quality issues of the manufactured packages, for instance what concerns burr and copper particles. Apart from this, a hybrid masking for copper etching of semiconductor packages may be advantageously implemented. A high speed saw, for example up to 300 mm/s, may be achieved on a mold compound. The described manufacturing architecture may be properly compatible with any package footprint, and may thus be flexible and scalable.

A preferred embodiment may provide a method to remove metal along a saw street. This may be achieved by etching prior to package singulation. Advantageously, this may enable high speed package singulation. A selective batch etching may be achieved by tin finishing to protect a large area from etching. Further advantageously, said tin may also be used as solder material. Preferably, a mold resin, a resist or a mask may be implemented at a focus area to define a targeted copper etching pattern. In an embodiment, a resist material may be only applied during a mask process before etching, and may be stripped off after etching. In an embodiment, said resin resist material will not remain on a final package. As an alternative, tin (as resist) can remain on a lead after etching to serve as finial finishing, for instance with target thickness of 5 μm to 30 μm, for example 10 μm. An undercut profile may be created at a sidewall of the carrier (for instance made of copper) and may be exposed without being tin plated. As resist material, it may be possible to use selective tin, selective epoxy type resist, etc. Said resist material (for example epoxy resin or tin) may serve as temporary mask material, or as final finishing (in particular in case of tin).

FIG. 1 illustrates a cross-sectional view of a package 100 according to an exemplary embodiment.

The illustrated power package 100 comprises a carrier 102 which is here embodied as copper leadframe structure, i.e. as a processed metal plate. In the shown embodiment, carrier 102 comprises two separate sections. An electronic component 104, which may be a semiconductor power chip, may be mounted on a first section, i.e. a die-pad portion, of the carrier 102. A terminal or pad of the electronic component 104 may be connected with a second section of the carrier 102 by an electrically conductive connection structure 109, such as a bond wire.

An encapsulant 106, preferably a mold compound, fully encapsulates the electronic component 104 and partially encapsulates the carrier 102. More precisely, part of a bottom surface 120 and a bottom part of a sidewall 108 of the carrier 102 are exposed beyond the encapsulant 106, whereas a top surface and a top part of the sidewall 108 of the carrier 102 are covered by the encapsulant 106.

In addition, the exposed bottom surface 120 is covered by a plating structure 118, which may be made of tin or which may comprise tin. Moreover, the aforementioned part of the bottom surface 120 covered by plating structure 118 and the exposed bottom portion of the sidewall 108 are covered by a further plating structure 118′, which may be made as well of tin or which may as well comprise tin, or which may be made of another material such as NiPdAu and/or NiPAu. Thus, said bottom surface 120 is directly covered by tin plating layer 118, which is further covered by the other plating layer 118′. Furthermore, said encapsulant-exposed portion of the sidewall 108 is directly covered by the other plating layer 118′.

As shown as well in FIG. 1, the sidewall 108 of the carrier 102 is concavely curved, and has an undercut 110. More precisely, the sidewall 108 comprises a lower curved part 112 and an upper curved part 114 connected with each other at an edge 116. Said curved parts 112, 114 may be formed by anisotropic etching processes, such as an alkaline etching process. As shown, the bottom surface 120 covered by tin plating layer 118 and the lower curved part 112 of sidewall 108 are covered by the same other plating layer 118′. Said other plating layer 118′ is made of a different material, preferably NiPdAu, than the tin plating layer 118. Said lower portion of the sidewall 108 is directly covered by the other plating layer 118′ without the tin plating layer 118 in between.

It should be emphasized that FIG. 1 shows only one exemplary embodiment. In other embodiments, the two curved parts 112, 114 of FIG. 1 may be absent. For example, the leadframe panel may be a flat piece (in particular at the bottom surface of the carrier structure), for instance made of copper, so that it may be free of a bottom recess (such a bottom recess is shown for instance in the first picture of FIG. 3, and is absent in FIG. 4). By using an alkaline etching process, it may be possible to create a single curved part in another embodiment. FIG. 2A illustrates a cross-sectional view of a structure obtained during manufacturing a package 100 according to an exemplary embodiment. In the embodiment of FIG. 2A, a pre-formed LTI (lead tip inspection) feature may be implemented.

FIG. 2A shows portions of two adjacent packages 100 manufactured based on an integral structure which is processed together during a batch manufacturing process before separating the individual packages 100 from each other. A bottom portion of the structure shown in FIG. 2A relates to a common carrier structure which has been separated into individual carriers 102. The separation of a common carrier structure into the individual carriers 102 may be carried out by selectively removing material of the common carrier structure by an alkaline etching process. This will be described below in further detail. Said alkaline etching process may contribute to the formation of the concavely curved sidewalls 108 of the separated structures. As will be described below as well, a tin plating layer 118 formed on bottom surface 120 and lower curved part 112 of sidewall 108 may function as an etch mask during said copper removal process. A further plating layer 118′ (for instance also made of tin or made of ENIG) may be formed on the tin plating layer 118 and on the upper curved part 114 of sidewall 108. After said separation of the common carrier structure into the individual carriers 102 according to FIG. 2A, the integral body will be held together only by the still integral encapsulant 106. For separating the common integral structure into the individual packages 100, material of encapsulant 106 in between will be removed by a (preferably mechanical) dicing process. This singulation may be carried out in a fast way, since the dicing process only needs to remove material of encapsulant 106, but no metallic material of the carriers 102.

In the embodiment of FIG. 2A, the bottom surface 120 and the bottom portion of the sidewall 108 are directly covered by integral common tin plating layer 118. A bottom part of another plating layer 118′ is deposited on the tin plating layer 118, whereas a top part of the other plating layer 118′ is deposited directly on the top portion of the sidewall 108 of the carriers 102.

A notch related to curved part 112 may be formed during a leadframe manufacturing process. The tin plating layer 118 may form an etch mask for ensuring a selective removal of copper material of carriers 102 by etching (in particular by an alkaline etch process) for forming the curved part 114.

FIG. 2B illustrates a cross-sectional view of a package 100 according to another exemplary embodiment.

The embodiment of FIG. 2B relates to a scenario in which an incoming leadframe panel is a copper sheet with a flat bottom surface. In such an embodiment, the obtained semiconductor package 100 may have only one curved part at the sidewall 108 of each pad or terminal of carrier 102, since there may be only a one-time alkaline etching process, which forms this single curved part extending along the sidewall 108 up to the bottom surface 120 of the carrier 102. FIG. 2B shows such an embodiment, whereas the curvature of sidewall 108 is not illustrated for the sake of simplicity. FIG. 3 illustrates cross-sectional views of structures obtained during manufacturing a package 100 according to an exemplary embodiment. Said obtained package 100 is shown on the bottom left-hand side of FIG. 3.

Referring to reference sign 160, a carrier structure 122 is provided which is embodied as a structured metal plate. For instance, carrier structure 122 may be a leadframe, for instance made of copper. The structured carrier structure 122 may optionally have bottom recesses 103 and top recesses 105. One usable leadframe panel is shown with reference sign 160, another usable leadframe panel may only have the top recesses 105 while the bottom may be flat (see FIG. 4). As shown in a detail 107 of FIG. 3, the top recesses 105 may be delimited by sidewalls having a curved part 114. A metallic coating 101, for instance comprising silver, may be formed on top surface portions (in particular on bond pads) of the carrier structure 122. Hence, reference sign 160 shows an incoming leadframe with silver on bond pads. A selective micro-etched tie bar 175 (or formed by laser engraving or stamping) is shown, for instance with a depth in a range from 0.5 μm to 1 μm.

Referring to reference sign 162, electronic components 104 (such as semiconductor chips) may be mounted on the carrier structure 122 provided for a plurality of packages 100 to be manufactured in common. Hence, reference sign 162 shows the result of die assembly on the metallic coating 101. Each electronic component 104 is assigned to a respective package 100 to be manufactured. At least one pad on the respective electronic component 104 may be coupled with a metallic coating 101 of the carrier structure 122 by an electrically conductive connection structure 109. Said electrically conductive connection structure 109 is here embodied as a bond wire, but may also be a clip (not shown). Still referring to reference sign 162, the electronic components 104 are fully encapsulated and the carrier structure 122 is partially encapsulated by an encapsulant structure 124 provided for the plurality of packages 100 to be manufactured in common. Preferably, encapsulant structure 124 is a mold compound. Tiny sections of encapsulant structure 124 may also fill the bottom recesses 103. Said mold resin bleed may function as resist mask in the continued manufacturing method. In other embodiments, there may be no such tiny sections of mold material.

Referring to reference sign 164, a tin layer 118 may then be applied or deposited for covering a part of a bottom surface of the carrier structure 122 which will be used as electrical terminals of the readily manufactured packages 100. While forming the tin layer 118, the sections of encapsulant structure 124 filling the bottom recesses 103 function as mask for defining portions of the carrier structure 122 to be covered by tin layer 118. To put it shortly, the manufacturing process according to reference sign 164 relates to selective tin plating or printing.

Referring to reference sign 166, sections of encapsulant structure 124 filling the bottom recesses 103 are removed. This process may be denoted as deflashing. Thus, material of the encapsulant structure 124 between adjacent parts of the carrier structure 122 covered by the tin layer 118 can be removed. This exposes sections of carrier structure 122.

Referring to reference sign 168, exposed material of the carrier structure 122 between adjacent packages 100 and within a respective package 100 being manufactured is selectively removed by an alkaline etching process. During said selective removal of exposed material, the tin layer 118 covering a bottom part of the carrier structure 122 functions as etch mask which will not be removed by the alkaline etching process. This process will selectively remove an exposed part of the carrier structure 122 being not covered by the tin layer 118 by the alkaline etching process. Alkaline copper etching is thus carried out during which tin can act as resist due to its stability against alkaline etchant. As a result, adjacent sections of the carrier structure 122 covered by the tin layer 118 are disconnected from each other to form now separated carriers 102 and now separated sections of a respective carrier 102. The obtained integral structure will be held together only by the material of the encapsulant 106, but no longer by material of the carrier structure 122.

As shown by a detail 111, the anisotropic alkaline etching process leads to carriers 102 with a sidewall 108 being concavely curved and having an undercut 110. More precisely, the sidewall 108 comprises a lower curved part 112 and an upper curved part 114 connected at an edge 116. Said lower curved part 112 may be formed by said anisotropic alkaline etching process. Thus, the concavely curved bottom part of sidewall 108 of the carrier 102 is caused by the alkaline etching process, while a bottom surface 120 of the obtained carrier 102 is formed planar without being etched thanks to the tin layer 118.

Referring to reference sign 170, after removing material of the carrier structure 122 by the alkaline etching process, the method may proceed in accordance with option 150 or option 152 shown in FIG. 3.

According to option 150, after removing material of the carrier structure 122, an additional conductive layer 118′ is deposited on the bottom surface 120 of the carrier 102 (or more precisely on the tin layer 118 on the bottom surface 120 of the carrier 102) and on the exposed portion of sidewall 108 of the carrier 102. Said additional conductive layer 118′ may comprise tin (to thereby form a tin double layer) or may comprise a material different from tin, for instance NiPdAu.

According to option 152, after removing material of the carrier structure 122, the tin layer 118 may be removed from bottom surface 120 of the carrier structure 122, for instance by tin stripping. Thereafter, an electrically conductive layer 118′ may be deposited directly on the exposed bottom surface 120 of the carrier 102 and a portion of sidewall 108 of the carrier 102 which has been exposed by the alkaline etching process. Preferably, the electrically conductive layer 118′ comprises a material different from tin, for instance NiPdAu.

Referring to reference sign 172, individual packages 100 may then be singulated from the still integral structure according to reference sign 170 (in both options 150, 152) by a separate subsequent process for fully separating the packages 100 from each other. This may be accomplished by removing material, which has been exposed by said selectively removing material of carrier structure 122, of the encapsulant structure 124 between adjacent packages 100. Said separate subsequent process can be a mechanical dicing process using mechanical dicing blades 113. As shown by reference sign 172, this dicing process can be executed by cutting through encapsulant material only, without cutting through metal of the carrier structure 122. This may lead to a high speed sawing process.

Referring to reference signs 168 and 172, the selective removal of carrier structure material and the separate subsequent process removing encapsulant material operate along the same direction, i.e. along a vertical direction. While the selectively removing locally thins an arrangement composed of the carrier structure 122 and the encapsulant structure 124, the separate subsequent dicing process forms a through hole extending through said arrangement and completes singulation of the packages 100.

As a result of the described manufacturing process, package 100 shown on the bottom left-hand side of FIG. 3 is obtained. The properties of package 100 may differ depending on which of options 150, 152 is followed:

In case of option 150, a portion of the bottom surface 120 of carrier 102 is directly covered by tin plating layer 118, which is further covered by other plating layer 118′, and a portion of the sidewall 108 of carrier 102 is directly covered by the other plating layer 118′.

In case of option 152, a portion of the bottom surface 120 and a portion of the sidewall 108 are directly covered by plating layer 118′ preferably made of electrically conductive material different from tin, for instance NiPdAu.

FIG. 4 illustrates cross-sectional al views of structures obtained during manufacturing a package 100 according to another exemplary embodiment. Said obtained package 100 is shown on the bottom left-hand side of FIG. 4.

The structure according to reference sign 174 differs from the structure according to reference sign 164 of FIG. 3 in that selective bottom portions of carrier structure 122 are covered by a mask 128 rather than being filled with encapsulant material in FIG. 4. Thus, before forming tin layer 118 and before selectively removing an exposed part of the carrier structure 122 during the transition from the structure according to reference sign 176 to the structure according to reference sign 178, resist mask 128 is formed between adjacent parts of the carrier structure 122 to be covered by the tin layer 118. Said resist mask 128 can be applied in particular after the encapsulating. Said resist mask 128 can be removed after forming tin layer 118, see reference sign 176 of FIG. 4. According to FIG. 4, the bottom main surface of carrier structure 122 is flat, i.e. does not comprise bottom recesses 103.

Reference sign 174 shows the result of a chip assembly process, formation of a resist or mechanical mask 128 (which may be for example pre-printed or assembled) on an exposed tie bar, and tin plating or printing.

Reference sign 176 shows the result of resist mask removal, which may be optional for pre-printed tin.

Reference sign 178 shows the result of an alkaline copper etching process for removing exposed copper material of carrier structure 122 to thereby form individual carriers 102 and individual sections of the carriers 102 for the various packages 100 to be formed. Removing material of carrier structure 122 being exposed beyond the tin layer 118 according to reference sign 178 of FIG. 4 can be a process corresponding to the process described above referring to reference sign 168 of FIG. 3.

Thereafter, any of options 150, 152, as described above, can be executed. Reference is made to reference sign 180 and the above description of reference sign 170 of FIG. 3.

After that, individual packages 100 may be singulated by mechanically dicing, see reference sign 182 of FIG. 4 corresponding to reference sign 172 of FIG. 3.

Depending on whether option 150 or option 152 has been applied, package 100 shown on the bottom left-hand side of FIG. 4 may have one of the two configurations concerning plating on bottom side 120 and sidewall 108 which have been described above referring to package 100 obtained according to FIG. 3.

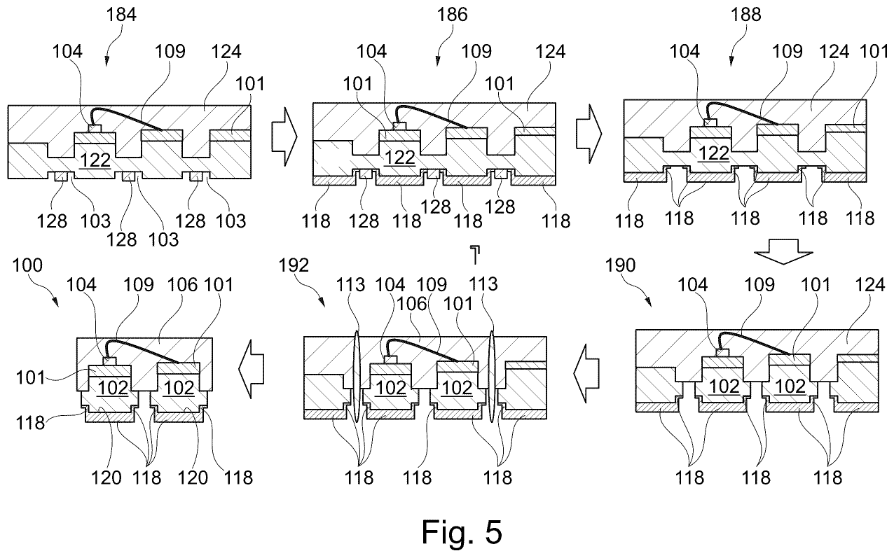

FIG. 5 illustrates cross-sectional views of structures obtained during manufacturing a package 100 according to another exemplary embodiment. Said obtained package 100 is shown on the bottom left-hand side of FIG. 5.

The embodiment according to FIG. 5 differs from the embodiment according to FIG. 4 in particular in that, according to FIG. 5, mask 128 may be formed before encapsulation. For instance, mask 128 of FIG. 5 may be embodied as resist being printed (for instance by inkjet printing) inside notches or bottom recesses 103 of carrier structure 122 from incoming leadframe material.

Reference sign 184 shows an assembly after molding and resist printing.

Reference sign 186 of FIG. 5 corresponds essentially to reference sign 174 of FIG. 4, with the difference concerning formation of mask 128 mentioned above.

Reference sign 188 of FIG. 5 corresponds essentially to reference sign 176 of FIG. 4, with the difference of a slightly different shape of tin layer 118 also extending partially in bottom recesses 103. Reference sign 186 shows the result of electrolytic tin plating. Reference sign 188 shows the result after resist mask removal.

Reference sign 190 of FIG. 5 corresponds essentially to reference sign 178 of FIG. 4, with the difference that tin layer 118 also covers sidewalls portions of carriers 102 according to FIG. 5.

Reference sign 192 of FIG. 5 corresponds essentially to reference sign 182 of FIG. 4 and shows singulation of packages 100.

The obtained packages 100 according to FIG. 5 have only a single tin layer 118 on the bottom surface 120 and on part of the sidewalls 108.

Although options 150, 152 are not shown in FIG. 5, they may be applied as well according to FIG. 5 for instance as described above referring to FIG. 4 or FIG. 3.

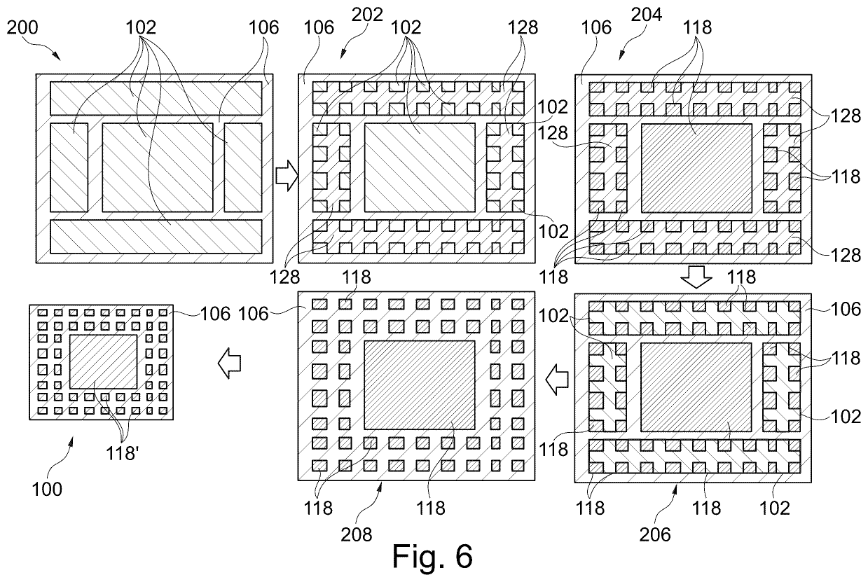

FIG. 6 illustrates plan views of structures obtained during manufacturing a package 100, being a multiple-row QFN-like package, according to an exemplary embodiment. More specifically, FIG. 6 shows bottom views of preforms of package 100.

Reference sign 200 illustrates a preform of package 100 after die attach, wire bonding and molding. Thus, reference sign 200 shows sections of a carrier 102 and of encapsulant 106.

Reference sign 202 illustrates a preform of package 100 after selective resist masking. Thus, reference sign 202 additionally shows a patterned mask 128.

Reference sign 204 illustrates a preform of package 100 after tin plating. Thus, reference sign 204 additionally shows sections of a tin layer 118.

Reference sign 206 illustrates a preform of package 100 after resist stripping. Thus, reference sign 206 shows the bottom surface after removing mask 128.

Reference sign 208 illustrates a preform of package 100 after selective copper etching. Thus, reference sign 208 shows the bottom surface after removing exposed material of carrier 102 by a selective alkaline etching process.

Package 100 is illustrated from a bottom side after ENIG (electroless nickel immersion gold) plating. Hence, further plating layer 118′ is here embodied as ENIG. Tin layer 118 may be removed by tin stripping, or main also remain below further plating layer 118′.

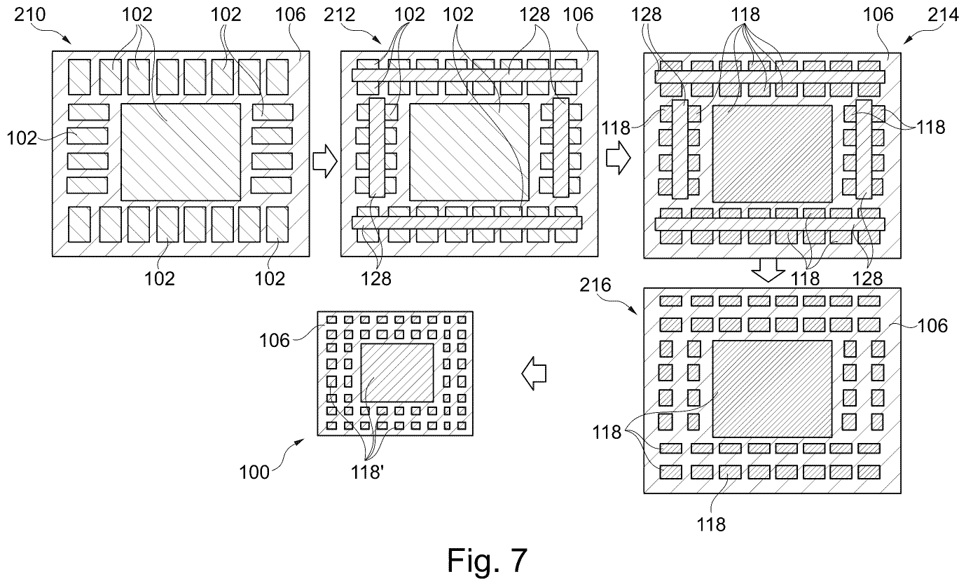

FIG. 7 illustrates plan views of structures obtained during manufacturing a package 100, being another multiple-row QFN-like package, according to another exemplary embodiment.

Reference sign 210 illustrates a preform of package 100 after die attach, wire bonding and molding. Thus, reference sign 210 shows sections of a carrier 102 and of encapsulant 106.

Reference sign 212 illustrates a preform of package 100 after selective resist masking. Thus, reference sign 212 additionally shows a patterned mask 128.

Reference sign 214 illustrates a preform of package 100 after tin plating. Thus, reference sign 214 additionally shows sections of a tin layer 118.

Reference sign 216 illustrates a preform of package 100 after resist stripping and copper etching. Thus, reference sign 216 shows the bottom surface after removing mask 128 and after removing exposed material of carrier 102 by a selective alkaline etching process.

Package 100 is illustrated from a bottom side after ENIG plating. Hence, further plating layer 118′ is here embodied as ENIG. Tin layer 118 may be removed by tin stripping, or main also remain below further plating layer 118′.

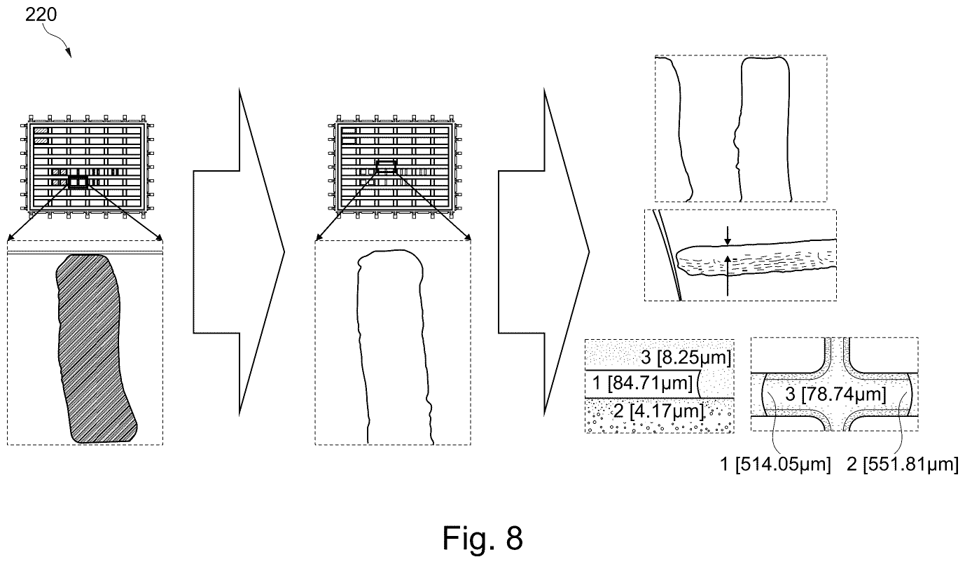

FIG. 8 illustrates images 220 obtained during manufacturing a package 100 according to an exemplary embodiment. Copper etching with selective masking has been executed to analyze the etched profile.

On the left-hand side of FIG. 8, a masked and tin plated sample is shown. A zoomed image on the bottom side illustrates a resist structure.

After resist stripping, as indicated by the arrow on the left-hand side of FIG. 8, the central image of FIG. 8 is obtained. A zoomed image on the bottom side illustrates a copper structure at the position of the former and now removed resist structure (i.e. in a resist striped area). Around the copper structure, a tin plated surface can be seen.

After half etching, as indicated by the arrow on the right-hand side of FIG. 8, the image on the right-hand side of FIG. 8 is obtained. On the top side, a tin plated surface and an etched area can be seen. In the middle, an etching depth of 0.1 mm (see double arrow) is shown in an etched area adjacent a tin plated surface. At the bottom left side, a section of a sample is shown with a small undercut with 1:1 aspect ratio. At the bottom right side, a top view of a mold compound surface is shown which is free from debris and contamination after etching. The undercut may be reduced significantly after spray pressure increase from 1.6 bar to 2.5 bar and lower etching speed (reduced from 1.2 m/min to 0.8 m/min).

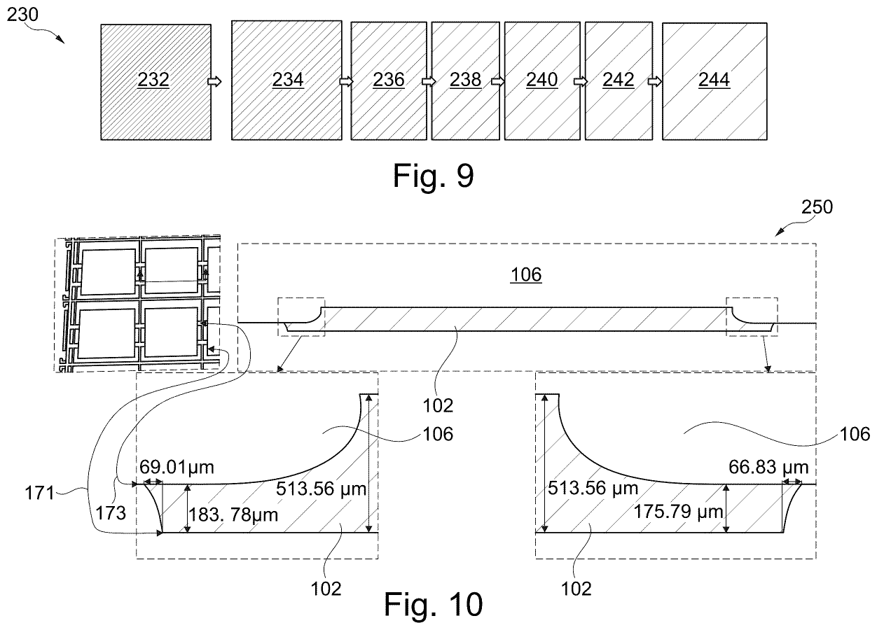

FIG. 9 illustrates a flowchart 230 of a method of manufacturing a package 100 according to an exemplary embodiment.

Referring to a block 232, a sequence of die attach, wire bonding, molding and deflashing can be executed.

Referring to a subsequent block 234, selective resist masking is executed by carrying out a sequence of pre-cleaning, ink-jet printing and curing.

Referring to a subsequent block 236, tin resist plating is executed.

Referring to a subsequent block 238, resist stripping is carried out, more precisely masking material may be stripped.

Referring to a block 240, alkaline copper etching is executed.

Referring to a subsequent block 242, tin resist stripping is done.

Referring to a subsequent block 244, a sequence of select coating, laser activation, copper and ENIG or tin plating, solder mask formation and sawing can be carried out.

According to a preferred embodiment, a selective tin plated surface may be enabled by an electrolytic tin process on a printed epoxy mask. Another advantageous process is selective alkaline etching on the leadframe with tin mask. An alkaline etchant may be preferably formed based on ammonium chloride. Thereafter, it may be preferred to strip off tin or to execute a tin stripping process. Alternatively, it may be possible to keep the tin as final finishing after the alkaline etching process. This may lead to an undercut profile with copper and tin plating.

FIG. 10 illustrates images obtained during manufacturing a package 100 according to an exemplary embodiment. FIG. 10 illustrate an etching profile of a copper frame structure with finishing plating layer indicated by arrows on the bottom side. Furthermore, FIG. 10 shows a cross section of the etched side wall of carrier 102 with plated tin mask. Regions without encapsulant 106 are created by the removal of metal by alkaline etching. Areas on the top side of carrier 102 may be filled with encapsulant 106. The curved upper recess may already come with an initial leadframe panel, and during the molding process, this curved upper recess may be filled with encapsulant 106. In a final package 100, arrow 171 may indicate the line of encapsulant 106, until the copper is etched away. Arrow 173 indicates the bottom surface of the package 100, also the area of encapsulant 106 where there was no copper existing.

It should be noted that the term “comprising” does not exclude other elements or features and the “a” or “an” does not exclude a plurality. Also elements described in association with different embodiments may be combined. It should also be noted that reference signs shall not be construed as limiting the scope of the claims. Moreover, the scope of the present application is not intended to be limited to the particular embodiments of the process, machine, manufacture, composition of matter, means, methods and steps described in the specification. Accordingly, the appended claims are intended to include within their scope such processes, machines, manufacture, compositions of matter, means, methods, or steps.

What is claimed is:

1. A package, comprising:
a carrier;
an electronic component mounted on the carrier; and
an encapsulant at least partially encapsulating the electronic component and partially encapsulating the carrier;
wherein at least a portion of a bottom surface and at least a portion of a sidewall of the carrier are exposed beyond the encapsulant;
wherein said at least portion of the bottom surface and said at least portion of the sidewall are covered at least partially by a plating structure having one of the following:
A) said at least portion of the bottom surface is directly covered by a tin plating layer, which is further covered by at least one other plating layer, and said at least portion of the sidewall is directly covered by the at least one other plating layer; or
B) said at least portion of the bottom surface and a one lower part of the side wall of at least portion of the sidewall are directly covered by a common tin plating layer, and at least part of at least one other plating layer which covers a section of the bottom surface and the lower part of the side wall, is deposited on the tin plating layer.

2. The package according to claim 1, wherein at least part of the sidewall of the carrier is curved, for example concavely curved, and has an undercut.

3. The package according to claim 1, wherein the sidewall comprises a lower curved part and an upper curved part connected at an edge, wherein in particular at least one of said curved parts is formed by an alkaline etching process.

4. The package according to claim 3, wherein the bottom surface and the lower curved part are covered by the same plating structure.

5. The package according to claim 1, wherein said at least one other plating layer is made of a different material, NiPdAu, than the tin plating layer, and said at least portion of the sidewall is directly covered by the at least one other plating layer without the tin plating layer in between.

6. The package according to claim 1, wherein the electronic component is configured as a power die.

7. The package according to claim 1, wherein the carrier comprises copper at least at its bottom surface or consists of copper.

8. The package according to claim 1, wherein the carrier is a leadframe structure.

9. A method of manufacturing packages, the method comprising:
mounting electronic components, at least one for each package being manufactured, on a carrier structure provided for the plurality of packages in common;
at least partially encapsulating the electronic components and partially encapsulating the carrier structure by an encapsulant structure provided for the plurality of packages in common;
after the encapsulating, selectively removing exposed material of the carrier structure at least between adjacent packages being manufactured; and
by a separate subsequent process, fully separating the packages by removing material, which has been exposed by said selectively removing, of the encapsulant structure between adjacent packages;
wherein said selectively removing exposed material comprises:
applying a tin layer covering part of the carrier structure which will be used as electrical terminals of the packages; and
removing selectively an exposed part of the carrier structure being not covered by the tin layer by an alkaline etching process so as to disconnect adjacent sections of the carrier structure covered by the tin layer;
the process after removal by the alkaline etching process also includes the following:
removal of the tin layer from a bottom surface of the support structure; and
deposition of at least one electrically conductive layer on the bottom surface of the support structure and a side wall of the support structure exposed by the alkaline etching process, the outermost surface of at least one electrically conductive layer having a material different from tin.

10. The method according to claim 9, wherein the method comprises, before the applying of the tin layer, applying a mask covering part of a bottom surface of the carrier structure, so as to expose another part of the bottom surface of the carrier structure for the subsequent applying of the tin layer.

11. The method according to claim 9, wherein, before said selectively removing the exposed part of the carrier structure, the method comprises at least partially removing at least one of:
a) material of the encapsulant structure between adjacent parts of the carrier structure covered by the tin layer, and/or
b) a resist mask between adjacent parts of the carrier structure covered by the tin layer, the resist mask being applied before the encapsulating; and/or
c) a resist mask between adjacent parts of the carrier structure covered by the tin layer, the resist mask being applied after the encapsulating and before the applying of the tin layer.

12. The method according to claim 9, wherein the separate subsequent process is a mechanical dicing process, wherein this dicing process is executed without cutting metal of the carrier structure.

13. The method according to claim 9, wherein the method comprises forming the tin layer and/or at least one additional conductive layer by a plating process.

14. The method according to claim 9, wherein the method comprises concavely curving at least part of a sidewall of the carrier structure by the alkaline etching process, while a bottom surface of the carrier structure is formed planar without being etched.

15. The method according to claim 9, comprising at least one of the following features:
wherein the selectively removing and the separate subsequent process remove material along the same direction;
wherein the selectively removing locally thins an arrangement composed of the carrier structure and the encapsulant structure, and the separate subsequent process forms a through hole extending through said arrangement;
wherein selectively removing material of the carrier structure comprises selectively removing metallic material, for example selectively removing copper material;
wherein the separate subsequent process does not remove metallic material;
wherein the method comprises using a leadframe as the carrier structure.
